(19) United States
(12) Patent Application Publication
(10) Pub. No.: US 2025/0218855 A1
(43) Pub. Date: Jul. 3, 2025

(54) SUBSTRATE SUPPORT UNIT AND HEAT TREATMENT DEVICE INCLUDING SAME

(71) Applicant: SEMES CO., LTD., Cheonan-si (KR)

(72) Inventors: Young Eun JEON, Cheonan-si (KR); Yun Sang KIM, Cheonan-si (KR); Jong Won PARK, Cheonan-si (KR); Woo Nam CHOI, Cheonan-si (KR); Tae Cheol SIM, Cheonan-si (KR); Jeong Sik KIM, Cheonan-si (KR)

(73) Assignee: SEMES CO., LTD., Cheonan-si (KR)

(21) Appl. No.: 19/004,240

(22) Filed: Dec. 28, 2024

(30) Foreign Application Priority Data
Dec. 28, 2023 (KR) 10-2023-0195052

(51) Int. Cl. H01L 21/687; H01L 21/67

(52) U.S. Cl. CPC H01L 21/68742; H01L 21/67115

(57) ABSTRACT

Proposed are a substrate support unit and a heat treatment device including the same. More particularly, proposed is a technology that controls a gas flow flowing over the surface of a substrate by using a pin assembly capable of adjusting inclination of the substrate, controls heat treatment of the substrate by differently supplying heat to each area of the substrate, and rapidly lowers the temperature of a substrate processing space and the substrate by using a cooling unit.

### CROSS REFERENCE TO RELATED APPLICATION

The present application claims priority to Korean Patent Application No. 10-2023-0195052, filed Dec. 28, 2023, the entire contents of which is incorporated herein for all purposes by this reference.

### BACKGROUND OF THE INVENTION

### Field of the Invention

The present disclosure relates generally to a substrate support unit and a heat treatment device including the same. More particularly, the present disclosure relates to a technology that controls a gas flow flowing over the surface of a substrate by using a pin assembly capable of adjusting inclination of the substrate, controls heat treatment of the substrate by differently supplying heat to each area of the substrate, and rapidly lowers the temperature of a substrate processing space and the substrate by using a cooling unit.

### Description of the Related Art

In order to manufacture a semiconductor device, a desired pattern is formed on a substrate by performing various processes such as photolithography, etching, ashing, ion implantation, thin film deposition, and cleaning. Of these various processes, the etching process is a process of removing a selected heated region in a film formed on the substrate, and uses wet etching and dry etching.

For dry etching, a process facility using plasma is used. Generally, in order to form plasma, an electromagnetic field is generated in an internal space of a chamber, and the electromagnetic field excites a process gas provided in the chamber into a plasma state.

Plasma refers to an ionized gaseous state composed of ions, electrons, radicals, and the like. Plasma is created by a very high temperature, a strong electric field, or an RF electromagnetic field. During the manufacture of a semiconductor device, the etching process is performed using plasma.

In a conventional plasma process facility, since adsorption and etching occur simultaneously during plasma etching, a problem arises in that fine etching control is difficult to achieve. Another problem is that attacks on a target underlying film and a change in diffusion roughness occur. Furthermore, since a process time through the conventional plasma process facility requires more than 60 minutes per process, a further problem arises in that unit per equipment hour (UPEH) is reduced.

There is thus a need for a semiconductor process facility that efficiently performs a plasma process and a heat treatment process to minimize target deterioration issues and improve UPEH.

Furthermore, since a lift pin disposed on a substrate support unit that supports a substrate and an alignment pin that prevents deviation of the substrate are individually provided, there arises a problem in that the device configuration becomes complicated. Additionally, when the lift pin is lifted and lowered, a further problem arises in that the alignment pin does not sufficiently reflect lifting and lowering of the lift pin, causing the substrate to deviate from its position.

Moreover, when performing a heat treatment process on the substrate, a still further problem arises in that a local temperature difference occurs on the substrate when a heat source is supplied uniformly to the entire area of the substrate.

### SUMMARY OF THE INVENTION

Accordingly, the present disclosure has been made keeping in mind the above problems occurring in the related art, and one objective of the present disclosure is to provide a semiconductor process facility that efficiently performs a plasma process and a heat treatment process, thereby minimizing target deterioration issues and improving UPEH.

In particular, another adjective of the present disclosure is to solve the problem in which the device configuration becomes complicated because a lift pin disposed on a substrate support unit that supports a substrate and an alignment pin that prevents deviation of the substrate are individually provided and the problem in which when the lift pin is lifted and lowered, the alignment pin does not sufficiently reflect lifting and lowering of the lift pin, causing the substrate to deviate from its position.

Moreover, another adjective of the present disclosure is to solve the problem in which when performing a heat treatment process on a substrate, a local temperature difference occurs on the substrate when a heat source is supplied uniformly to the entire area of the substrate.

The objectives of the present disclosure are not limited to those mentioned above, and other objectives not mentioned and advantages of the present disclosure will be clearly understood from the following description.

In order to achieve the above objectives, according to one aspect of the present disclosure, there is provided a substrate support unit, including: a substrate support configured to support a substrate; a plurality of pin assemblies spaced apart from each other at an outer portion of the substrate support and each of which includes a lift pin configured to lift and lower the substrate, a guide tip located outside the lift pin and configured to guide the substrate to be prevented from deviating from its position, and a body on which the lift pin and the guide tip are arranged to correspond to each other; and a pin lifting means configured to lift and lower the bodies of the plurality of pin assemblies to adjust a height of the substrate.

As an example, each of the plurality of pin assemblies may be configured such that the lift pin, the guide tip and the body are formed integrally.

Alternatively, each of the plurality of pin assemblies may be configured such that a lift pin mounting hole and a guide tip mounting hole are provided in the body and the lift pin and the guide tip are insertedly coupled to the body.

Preferably, an upper end of the guide tip that guides the substrate may be inclined.

Preferably, each of the plurality of pin assemblies may be made of a quartz material.

Additionally, the substrate support unit may further include: a plurality of pin lifting means configured to lift and lower the plurality of pin assemblies, respectively; and a substrate height controller configured to control each of the plurality of pin lifting means to adjust a lifting height of each of the plurality of pin assemblies.

As an example, the substrate support unit may further include: a plurality of pin lifting means configured to lift a plurality of pin assembly groups, respectively, each of the plurality of pin assembly groups being composed of at least one selected from the plurality of pin assemblies; and a substrate height controller configured to control each of the plurality of pin lifting means to adjust a lifting height of each of the plurality of pin assembly groups.

As an example, the substrate height controller may adjust inclination of the substrate by individually controlling the plurality of pin lifting means so that the plurality of pin assembly groups have different lifting heights.

According to another aspect of the present disclosure, there is provided a heat treatment device, including: a heat treatment chamber configured to provide a heat treatment space for a substrate; the first substrate support unit disposed in the heat treatment space of the heat treatment chamber; and a heat source unit configured to supply heat for heat treatment of the substrate.

As an example, the heat source unit may include: a plurality of lamps; and a heat source controller configured to divide the plurality of lamps into a plurality of heat source regions and control operation of the plurality of lamps for each of the plurality of heat source regions.

As an example, the heat source unit may be configured such that the plurality of lamps are arranged in different numbers for each of the plurality of heat source regions.

As an example, the heat source unit may be configured such that the heat source regions are divided into a central heat source region, and an outer heat source region and the plurality of lamps are arranged in a plurality of layers in each of the plurality of heat source regions by adjusting arrangement density of the plurality of lamps.

As an example, the heat source control unit may control output of the plurality of lamps differently for each of the plurality of heat source regions.

Additionally, the heat treatment device may further include: a side wall refrigerant flow path formed at a wall of the heat treatment chamber; and a refrigerant supplier configured to supply a refrigerant to the side wall refrigerant flow path.

As an example, the side wall refrigerant flow path may be provided in a zigzag shape on the wall of the heat treatment chamber.

Additionally, the heat treatment device may further include: a bottom refrigerant flow path formed in the substrate support unit; and a refrigerant supplier configured to supply a refrigerant to the bottom refrigerant flow path.

As an example, the bottom refrigerant flow path may be configured such that a portion corresponding to the substrate seated on the substrate support unit is divided into a plurality of regions to form a refrigerant flow path for each of the regions.

Additionally, the heat treatment device may further include: a gas supply unit configured to selectively supply an environment-forming gas or purge gas to the heat treatment space of the heat treatment chamber.

As an example, the substrate support unit may adjust inclination of the substrate by differently adjusting lifting heights of the plurality of pin assemblies, and the substrate support unit may adjust a flow of the environment-forming gas or purge gas from a first side of the substrate that is relatively high to a second side of the substrate that is relatively low through adjustment of inclination of the substrate.

According to another aspect of the present disclosure, there is provided a heat treatment device, including: a heat treatment chamber configured to provide a heat treatment space for a substrate; a substrate support unit disposed in the heat treatment space of the heat treatment chamber, and including a substrate support configured to support a substrate, a plurality of pin assemblies spaced apart from each other at an outer portion of the substrate support and each of which includes a lift pin configured to lift and lower the substrate, a guide tip located outside the lift pin and configured to guide the substrate to be prevented from deviating from its position, and a body on which the lift pin and the guide tip are arranged to correspond to each other, and a pin lifting means configured to lift and lower the bodies of the plurality of pin assemblies to adjust a height of the substrate; a plurality of pin lifting means configured to lift a plurality of pin assembly groups, respectively, each of the plurality of pin assembly groups being composed of at least one selected from the plurality of pin assemblies; a substrate height controller configured to control each of the plurality of pin lifting means to adjust a lifting height of each of the plurality of pin assembly groups and configured to adjust inclination of the substrate by individually controlling the plurality of pin lifting means so that the plurality of pin assembly groups have different lifting heights; a heat source unit configured to divide a portion corresponding to the substrate into a plurality of heat source regions, and including a plurality of lamps arranged in each of the plurality of heat source regions by adjusting arrangement density of the plurality of lamps according to the number of the plurality of lamps, and a heat source controller configured to control operation of the plurality of lamps for each of the plurality of heat source regions; a side wall refrigerant flow path formed at a wall of the heat treatment chamber; a bottom refrigerant flow path formed in the substrate support of the substrate support unit; a refrigerant supplier configured to supply a refrigerant to the side wall refrigerant flow path and the bottom refrigerant flow path; and a gas supply unit configured to supply an environment-forming gas or purge gas to the heat treatment space of the heat treatment chamber. The substrate support unit may adjust a flow of the environment-forming gas or purge gas from a first side of the substrate that is relatively high to a second side of the substrate that is relatively low through adjustment of inclination of the substrate.

According to the present disclosure, it is possible to provide a semiconductor process facility that efficiently performs a plasma process and a heat treatment process, thereby minimizing target deterioration issues and improving UPEH.

In particular, by providing a pin assembly, which has a lift pin for lifting and lowering a substrate and a guide tip for preventing deviation of the substrate in one body, it is possible to enable the lift pin and the guide tip to be operated simultaneously, thereby stably maintaining the position of the substrate.

Furthermore, by adjusting the inclination of the substrate by differently adjusting the heights of a plurality of pin assemblies, it is possible to control the flow of gas to flow along the surface of the substrate, thereby further increasing the efficiency of the heat treatment process.

Additionally, by controlling heat source supply to each area of the substrate, it is possible to enable a uniform heat treatment process to be performed on the entire substrate.

Moreover, by shortening the heat treatment process time, it is possible to prevent deterioration of a process target.

The effects of the present disclosure are not limited to those mentioned above, and other effects not mentioned will be clearly understood by those skilled in the art from the following description.

### BRIEF DESCRIPTION OF THE DRAWINGS

The above and other objects, features, and other advantages of the present disclosure will be more clearly understood from the following detailed description when taken in conjunction with the accompanying drawings, in which:

FIG. 1 is a basic configuration view illustrating an embodiment of a substrate processing system according to the present disclosure;

FIG. 2 is a view illustrating an embodiment of a plasma process device in a dual process facility of the substrate processing system according to the present disclosure;

FIG. 3 is a view illustrating an embodiment of a heat treatment device in the dual process facility of the substrate processing system according to the present disclosure;

FIGS. 4 and 5 are views illustrating an embodiment of a substrate support unit according to the present disclosure;

FIGS. 6 to 8 are views illustrating an embodiment of a pin assembly of the substrate support unit according to the present disclosure;

FIG. 9 is a view illustrating an embodiment of inclinedly lifting and lowering a substrate by using the substrate support unit according to the present disclosure;

FIGS. 10 and 11 are views illustrating another embodiment of a substrate support unit according to the present disclosure;

FIGS. 12A and 12B are views illustrating an embodiment of a heat source unit provided in the heat treatment device according to the present disclosure;

FIG. 13 and FIGS. 14A, 14B, and 14C are views illustrating an embodiment of a cooling unit provided in the heat treatment device according to the present disclosure; and

FIGS. 15A and 15B and FIG. 16 are views illustrating an embodiment of controlling a gas flow in the heat treatment device according to the present disclosure.

### DETAILED DESCRIPTION OF THE INVENTION

Hereinafter, exemplary embodiments of the present disclosure will be described in detail with reference to the accompanying drawings, but the present disclosure is not limited by these embodiments.

The present disclosure, operational advantages of the present disclosure, and objectives achieved by executing the present disclosure will be, hereinafter, described by exemplifying preferred embodiments of the present disclosure and referring to the exemplified embodiments.

First, terms used herein is for the purpose of describing particular embodiments only and is not intended to be limiting. As used herein, the singular forms are intended to include the plural forms as well, unless the context clearly indicates otherwise. Further, it will be understood that the terms “comprise”, “include”, and/or “have” when used herein, specify the presence of stated features, integers, steps, operations, elements, and/or components, but do not preclude the presence or addition of one or more other features, integers, steps, operations, elements, components, and/or groups thereof.

In the following description, a detailed description of related known configurations or functions may be omitted to avoid obscuring the subject matter of the present disclosure.

The present disclosure proposes a technology that controls a gas flow flowing over the surface of a substrate by using a pin assembly capable of adjusting inclination of the substrate, controls heat treatment of the substrate by differently supplying heat to each area of the substrate, and rapidly lowers the temperature of a substrate processing space and the substrate by using a cooling unit.

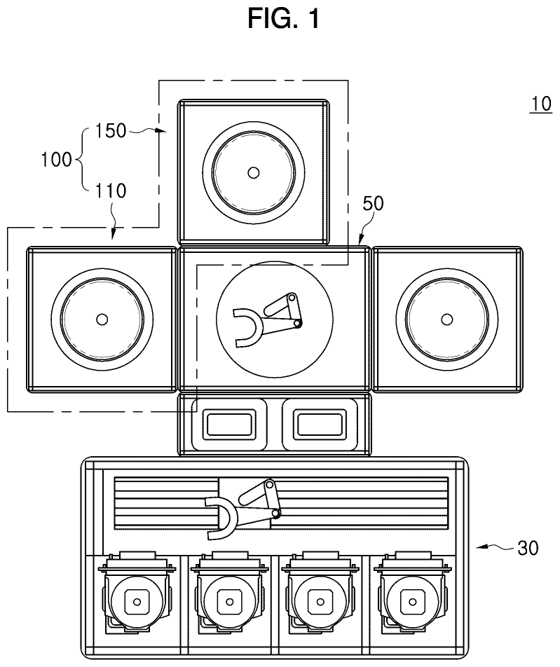

FIG. 1 is a basic configuration view illustrating an embodiment of a substrate processing system according to the present disclosure.

The substrate processing system 10 may include a dual process facility 100, an index module 30, and the like.

In the dual process facility 100, a device that performs an adsorption process through plasma treatment on a substrate and a device that performs an etching process through heat treatment on a substrate may be separately configured.

As an example, the dual process facility 100 may include a plasma process device 110 and a heat treatment device 150.

Through the dual process facility 100, the adsorption process using the plasma process device 110 and the etching process using the heat treatment device 150 may be performed in a repetitive cycle during etching of the substrate.

The plasma process device 110 of the dual process facility 100 may employ various types of plasma process devices such as capacitively coupled plasma (CCP), inductively coupled plasma (ICP), and microwave-induced plasma.

In addition to the dual process facility 100, a single process facility may also be included. In the single process facility, the adsorption process through plasma treatment and the etching process through heat treatment may be performed by a single device. A detailed description of the single process facility will be omitted.

The index module 30 may supply a substrate to the dual process facility 100.

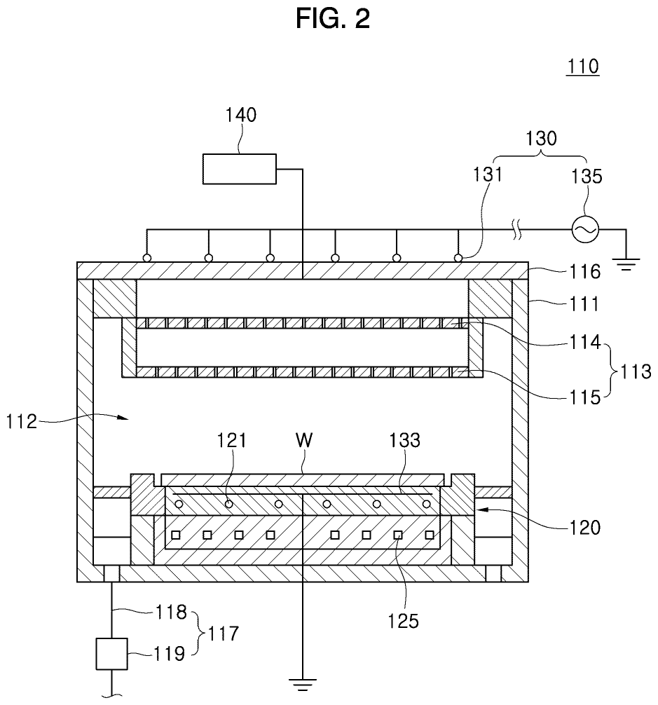

As an example of applying a capacitively coupled plasma (CCP) method in relation to the plasma process device 110 of the dual process facility 100, FIG. 2 illustrates an embodiment of a plasma process device in the dual process facility of the substrate treatment system according to the present disclosure.

The plasma process device 110 may include a plasma process chamber 111, a substrate support unit 120, a plasma generation unit 130, a gas supply unit 140, and the like. Additionally, an ion blocker 113 may be provided in the plasma process chamber 111 of the plasma process device 110.

The plasma process chamber 111 may provide a plasma treatment space 112 for performing a plasma treatment process on a substrate W. As an example, the plasma process chamber 111 may be a cylindrical vacuum chamber.

A chamber cover 116 may be disposed at an upper portion of the plasma process chamber 111 to seal the plasma treatment space 112 of the plasma process chamber 111.

A door means (not illustrated) for entering and exiting the substrate W may be installed at a side wall of the plasma process chamber 111. The substrate W may be brought in and out of the plasma treatment space 112 of the plasma process chamber 111 through the door means.

An exhaust part 117 may be installed at a lower portion of the plasma process chamber 111. The exhaust part 117 may include an exhaust pipe 118, a vacuum pump 119, and the like. The exhaust part 117 may adjust the pressure of the plasma treatment space 112 of the plasma process chamber 111 to a desired vacuum level by using the vacuum pump 119 such as a turbo molecular pump. Additionally, the exhaust part 117 may discharge process by-products and residual process gases generated in the plasma process chamber 111.

An area that comes into contact with a process gas, such as a wall portion of the plasma process chamber 111, may be made of a material such as aluminum ceramic (Al ceramic).

The substrate support unit 120 may be disposed in the plasma treatment space 112 of the plasma process chamber 111. The substrate support unit 120 may support the substrate W.

The substrate support unit 120 may include an electrostatic chuck (ESC) that adsorbs and supports the substrate W by an electrostatic force. Depending on situations, the substrate support unit 120 may include various substrate support means capable of fixing and supporting the substrate W by mechanical clamping or fixing and supporting the substrate W by a vacuum suction force.

The substrate support unit 120 may adjust the temperature of the substrate W during plasma treatment for the substrate W. For this purpose, the substrate support unit 120 may be provided with a heating member 121 and a cooling member 125. As an example, the temperature of the substrate W may be raised and adjusted to a set high temperature by using the heating member 121. Additionally, the temperature of the substrate W may be lowered and adjusted to a set low temperature by using the cooling member 125.

The plasma generation unit 130 may activate a plasma in the plasma treatment space 112 of the plasma process chamber 111.

The plasma generation unit 130 may include an upper electrode 131, a lower electrode 133, an RF power supplier 135, and the like.

The upper electrode 131 may include a radio frequency (RF) antenna. The antenna may have a planar coil shape. The chamber cover 116 may include a disc-shaped dielectric window. The dielectric window may include a dielectric material. As an example, the dielectric window may include aluminum oxide (Al2O3). The dielectric window may function to transmit power from the antenna to the inside of the plasma process chamber 111.

As an example, the upper electrode 131 may include spiral- or concentric circular-shaped coils. Here, the number, arrangement, and the like of the coils may be appropriately changed as needed.

The RF power supplier 135 may apply a plasma source power to the upper electrode 131. The RF power supplier 135 may generate an RF signal and apply the RF signal to the upper electrode 131.

The lower electrode 133 may be disposed inside the substrate support unit 120. The lower electrode 133 may be grounded or connected to a bias power source.

The gas supply unit 140 may supply a process gas into the plasma process chamber 111, and may also supply a carrier gas into the plasma process chamber 111 in addition to the process gas.

As the process gas, various process gases may be selected depending on the characteristics of a target substrate processed with plasma. Preferably, since the area that comes into contact with the process gas, such as the wall portion of the plasma process chamber 111, is made of a material such as aluminum ceramic (Al ceramic), a gas that excludes or minimizes the use of fluorine (F)-based gas or hydrogen (H)-based gas may be used. That is, the process gas introduced during plasma treatment may be selected to prevent corrosion of the area that comes into contact with the process gas, such as the wall portion of the plasma process chamber 111.

The carrier gas is a gas that does not react with the process gas and does not react with an upper surface of the substrate W, and may include an inert gas such as argon (Ar).

Furthermore, the gas supply unit 140 may include a flow rate controller (FRC) and the like to adjust the supply amount of the process gas and the supply amount of the carrier gas. As an example, the FRC may include a mass flow controller (MFC).

The ion blocker 113 may be disposed in an upper space inside the plasma process chamber 111 to partition the plasma treatment space 112. As an example, the ion blocker 113 may form an upper plasma space above the ion blocker 113 and a lower plasma space above the substrate W.

As an example, the ion blocker 113 may include an upper plate 114 and a lower plate 115, and may include a diffusion space provided between the upper plate 114 and the lower plate 115.

The upper plate 114 may be provided with a plurality of gas inlet holes as through-holes that allow a gas from the upper plasma space to be introduced into the diffusion space. The lower plate 115 may be provided with a plurality of gas outlet holes as through-holes that allow a gas in the diffusion space to be diffused into the lower plasma space.

The plurality of gas inlet holes provided in the upper plate 114 and the plurality of gas outlet holes provided in the lower plate 115 may be arranged so that their imaginary extension lines are misaligned with each other. That is, imaginary extension holes extending from the gas inlet holes of the upper plate 114 meet an upper surface of the lower plate 115 and are blocked thereby, and imaginary extension holes extending from the gas outlet holes of the lower plate 115 meet a lower surface of the upper plate 114 and are blocked thereby.

The number, arrangement form, and the like of the gas inlet holes of the upper plate 114 and the gas outlet holes of the lower plate 115 may be variously changed as needed.

Through the structure of the ion blocker 113, ions may be filtered while radicals may be diffused to the surface of the substrate W.

When the plasma treatment process is performed on the substrate W by using the plasma process device 110, radicals for etching may be adsorbed to the substrate W.

Next, the heat treatment device 150 of the dual process facility 100 will be described. The heat treatment device 150 may perform an etching process through heat treatment on the substrate W by emitting heat from at least one heat source among various heat sources such as a flash lamp, a laser generator, or a microwave generator.

As an example, the flash lamp may provide light as heating energy. The laser generator may provide laser as heating energy. The microwave generator may provide microwave as heating energy.

Preferably, a heat source using a lamp may be applied to the heat treatment device 150 of the dual process facility 100 so as to be suitable for performing a heating process for a long period of time. That is, in the dual process facility 100, since the number of heat treatment devices 150 may be increased compared to the number of plasma process devices 110, a substrate processing operation that requires a long-term heat treatment process may be performed through the dual process facility 100.

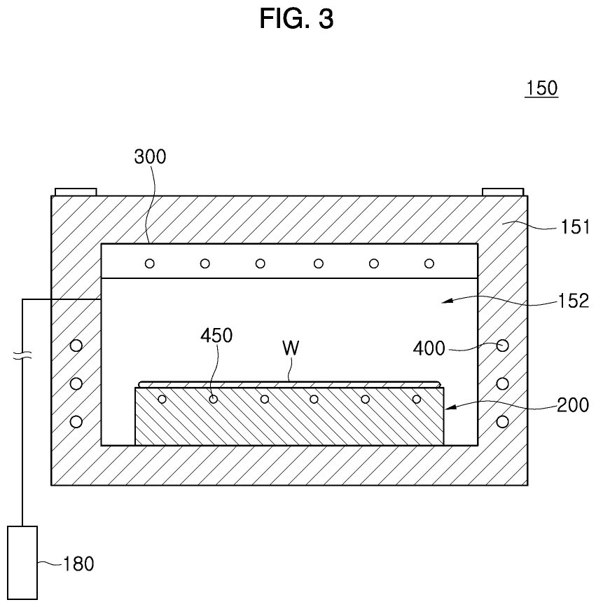

As an example of applying a heat source of a lamp to the heat treatment device 150 of the dual process facility 100, FIG. 3 illustrates an embodiment of a heat treatment device in the dual process facility of the substrate processing system according to the present disclosure.

The heat treatment device 150 may include a heat treatment chamber 151, a substrate support unit 200, a heat source unit 300, a gas supply unit 180, and the like.

The heat treatment chamber 151 may provide a heat treatment space 152 for performing a heat treatment process on the substrate W.

The substrate support unit 200 may be disposed in the heat treatment space 152 of the heat treatment chamber 151. The substrate W may be seated and supported on the substrate support unit 200.

The heat source unit 300 may be disposed at an upper portion of the heat treatment space 152 of the heat treatment chamber 151.

The heat source unit 300 may include a lamp. Preferably, the heat source unit 300 may include a plurality of lamps 171 arranged corresponding to the size of the substrate W. The lamps 171 may emit light energy, and the light energy emitted from the lamps 171 may be provided to the substrate W.

As an example, the number of lamps may be adjusted by dividing the lamps into regions corresponding to the substrate, and heat emission control of each lamp may be performed differently. This will be described in detail later through embodiments.

The substrate W may be rapidly heated and raised to a set temperature range by light energy emitted from the heat source unit 300.

Additionally, the heat treatment device 150 may further include cooling units 400 and 450.

The cooling unit 400 may be disposed at a side wall of the heat treatment chamber 151 to cool the heat treatment space 152 and the substrate W. Additionally, the cooling unit 450 may be disposed in the substrate support unit 200 to cool the substrate W.

As an example, each of the cooling units 400 and 450 may include a cooling flow path and a refrigerant supplier for supplying a refrigerant to the cooling flow path. This will be described in detail later through embodiments.

The gas supply unit 180 may supply an environment-forming gas for forming a heat treatment environment in the heat treatment space 152 of the heat treatment chamber 151 and a purge gas for etching the substrate W through heat treatment. As an example, the environment-forming gas may be an inert gas such as N2, Ar, or He so that it is not induced to react with other gases and does not react with the surface of the substrate W.

The heat treatment device 150 may shorten a process time by rapidly heat treating the substrate W and ensure etching uniformity by heating and cooling the substrate W.

Each configuration provided in the heat treatment device 150 will be described in more detail through embodiments.

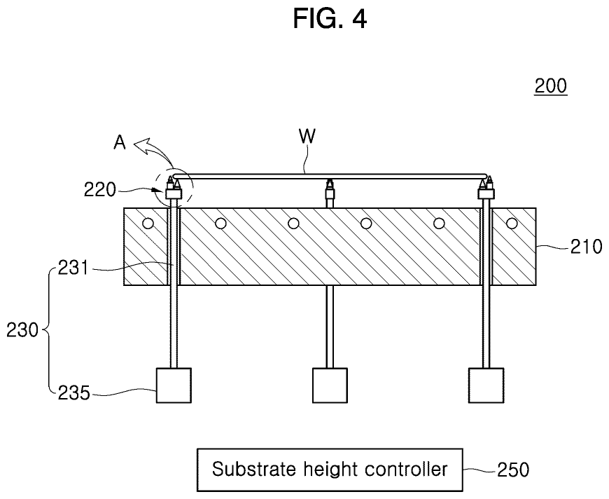

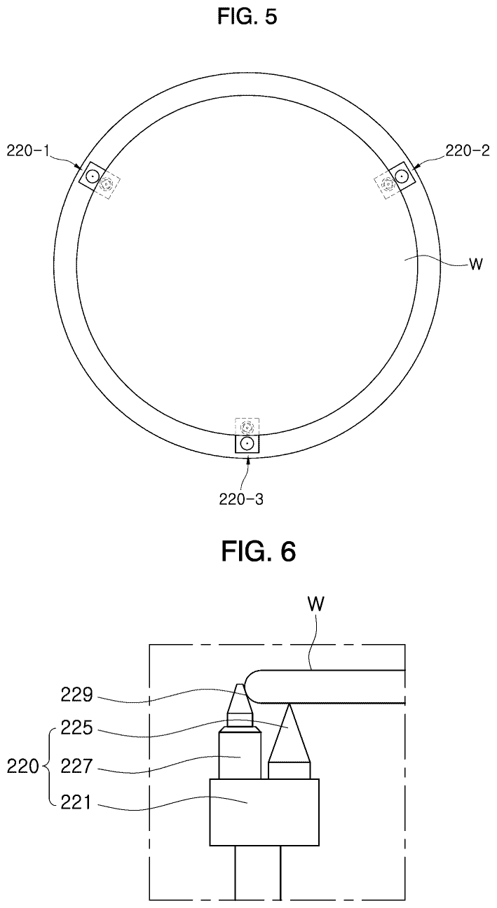

FIGS. 4 and 5 are views illustrating an embodiment of a substrate support unit according to the present disclosure.

The substrate support unit 200 according to the present disclosure may include a substrate support 210, a pin assembly 220, a pin lifting means 230, a substrate height controller 250, and the like.

The substrate support 210 may support the substrate W. More specifically, the substrate W may be seated and supported on the pin assembly 220 disposed on the substrate support 210.

The pin assembly 220 may be lifted and lowered relative to an upper portion of the substrate support 210. The pin assembly 220 may support the substrate W seated thereon and prevent the substrate W from deviating from its position.

A plurality of pin assemblies 220 may be arranged along the circumference of the substrate W. As an example, as illustrated in FIG. 5, three pin assemblies 220-1, 220-2, and 220-3 may be arranged spaced apart from each other along the circumference of the substrate W. The number and arrangement positions of the pin assemblies may be appropriately changed as needed.

The substrate height controller 250 may adjust the height of the substrate W by controlling the pin lifting means 230 to lift and lower the pin assembly 220.

The pin lifting means 230 may include a lift bar 231, a lift driver 235, and the like. The lift bar 231 may pass through the substrate support unit 200 to be connected to a lower end of the pin assembly 220 and may lift and lower the pin assembly 220. The lift driver 235 may be provided with a linear motor or the like to move the lift bar 231 in a vertical direction.

The substrate height controller 250 may adjust the height of the substrate W seated on the pin assembly 220 by controlling the pin lifting means 230.

In relation to the pin assembly, FIGS. 6 to 8 illustrate an embodiment of a pin assembly of the substrate support unit according to the present disclosure. FIG. 6 is an enlarged view of part A in FIG. 4.

The pin assembly 220 may include a lift pin 225, a guide tip 227, a body 221, and the like.

The lift pin 225 may lift the substrate W by making contact with a lower surface of the substrate W.

The guide tip 227 may be located outside the lift pin 225 and guide the substrate W so as not to deviate from its position.

The lift pin 225 and the guide tip 227 may be arranged on the body 221 so as to correspond to each other.

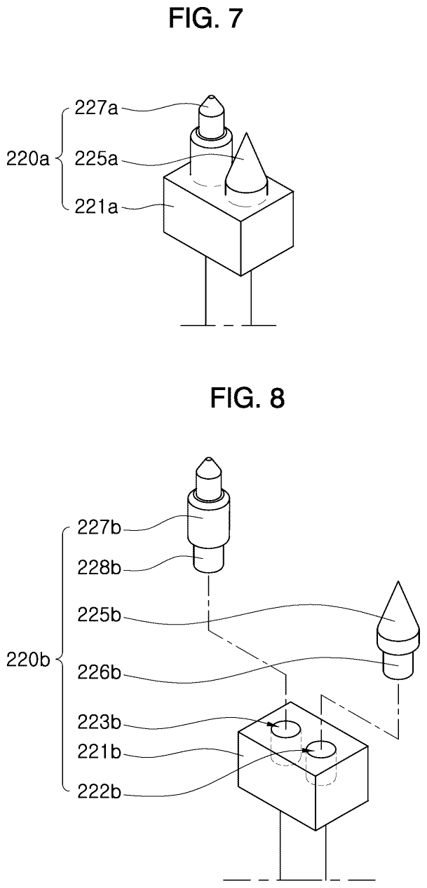

As an example, as illustrated in FIG. 7, a pin assembly 220a may be configured such that a lift pin 225a and a guide tip 227a protrude from an upper portion of a body 221a and are formed integrally. For example, the body 221a, the lift pin 225a, and the guide tip 227a may be made of a quartz material and formed into a single integrated pin assembly 220a.

As another example, as illustrated in FIG. 8, a pin assembly 220b may be configured such that a body 221b, a lift pin 225b, and a guide tip 227b are manufactured separately and then assembled together.

The body 221b may be provided with a lift pin mounting hole 222b and a guide tip mounting hole 223b, and mounting protrusions 226b and 228b may be provided at the lower portions of the lift pin 225b and the guide tip 227b, respectively. The lift pin 225b and the guide tip 227b may be inserted and coupled to the lift pin mounting hole 222b and the guide tip mounting hole 223b of the body 221b.

Each of the body 221b, the lift pin 225b, and the guide tip 227b may be made of a quartz material.

An upper end of the guide tip 227 may be inclined to form an inclined portion 229. The inclined portion 229 of the guide tip 227 may guide a side surface of the substrate W to prevent misalignment and deviation of the substrate W.

In particular, when the substrate W is lifted or lowered inclinedly, which will be described later, the side surface of the substrate W may be brought into contact with the inclined portion 229 of the guide tip 227, thereby preventing the substrate W from slipping and deviating in one direction.

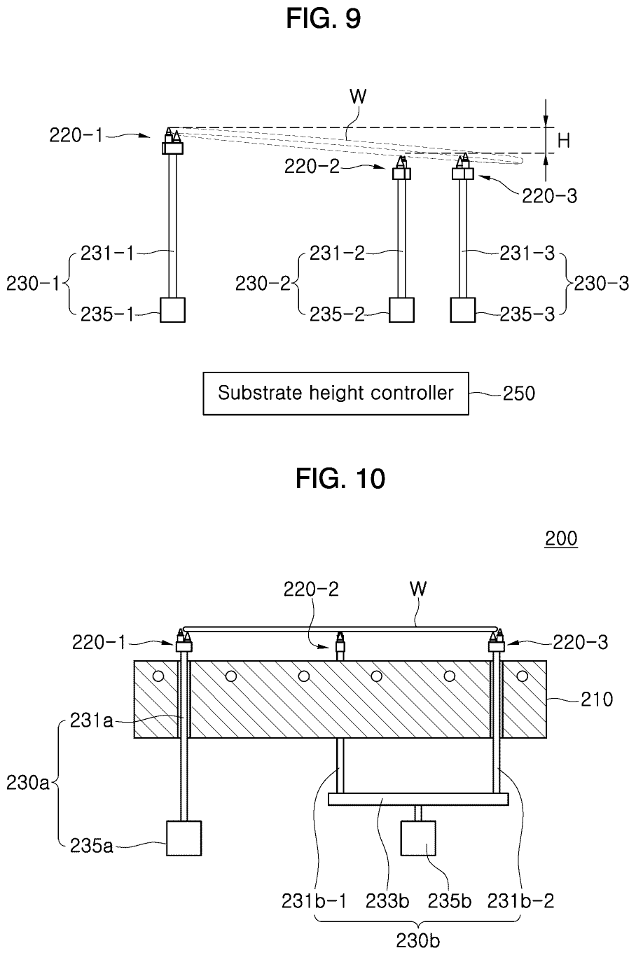

Furthermore, in the present disclosure, the pin lifting means may be controlled to lift and lower a plurality of pin assemblies at different heights, thereby allowing the substrate to be lifted and lowered inclinedly. In relation to this, FIG. 9 illustrates an embodiment of inclinedly lifting and lowering the substrate by using the substrate support unit according to the present disclosure.

First to third pin assemblies 220-1, 220-2, and 220-3 may be provided with first to third pin lifting means 230-1, 230-2, and 230-3, respectively.

The substrate height controller 250 may individually control the first to third pin lifting means 230-1, 230-2, and 230-3.

As illustrated in FIG. 9, the first pin assembly 220-1 may be connected to a first lift bar 231-1 of the first pin lifting means 230-1, and the first pin assembly 220-1 may be lifted and lowered by operation of a first lift driver 235-1. Likewise, the second and third pin assemblies 220-2 and 220-3 may be connected to second and third lift bars 231-2 and 231-3 of the second and third pin lifting means 230-2 and 230-3, respectively, and the second and third pin assemblies 220-2 and 220-3 may be lifted and lowered by operations of second and third lift drivers 235-2 and 235-3, respectively.

The substrate height controller 250 may control the first pin lifting means 230-1 to lift the first pin assembly 220-1 to a relatively higher height and control the second and third pin lifting means 230-2 and 230-3 to lift the second and third pin assemblies 220-2 and 220-3 to a relatively lower height.

As such, the substrate height controller 250 may adjust an inclination height H of the substrate W by adjusting lifting heights of the first to third pin assemblies 220-1, 220-2, and 220-3.

At this time, inclined portions of the guide tips of the second and third pin assemblies 220-2 and 220-3 may guide the side surface of the substrate W in a contact manner so that the substrate W is prevented from slipping downward and deviating from its position.

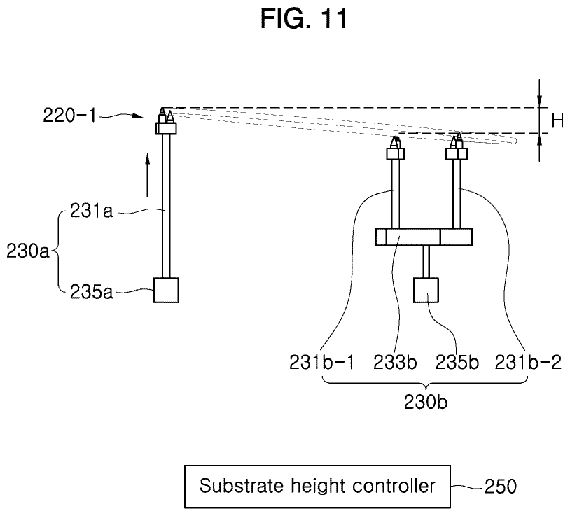

FIGS. 10 and 11 are views illustrating another embodiment of a substrate support unit according to the present disclosure.

In describing this embodiment, configurations that overlap with those of the previously discussed embodiments will be omitted or briefly described.

The substrate support unit 200 may be provided with first to third pin assemblies 220-1, 220-2, and 220-3. The one first pin assembly 220-1 may form an independent first pin assembly group, and the two second and third pin assemblies 220-2 and 220-3 may form one second pin assembly group.

A first pin lifting means 230a may be provided corresponding to the first pin assembly group, and a second pin lifting means 230b may be provided corresponding to the second pin assembly group.

A lift bar 231a of the first pin lifting means 230a may be connected to the first pin assembly 220-1 constituting the first pin assembly group. The height of the first pin assembly 220-1 constituting the first pin assembly group may be adjusted by a lift driver 235a.

That is, since the first pin assembly group is formed by only the one first pin assembly 220-1, the height of the first pin assembly 220-1 may be individually adjusted.

The second pin lifting means 230b may be provided with two lift bars 231b-1 and 231b-2 corresponding to the second and third pin assemblies 220-2 and 220-3 constituting the second pin assembly group. The two lift bars 231b-1 and 231b-2 may be connected to each other through a connecting bar 233b. The heights of the second and third pin assemblies 220-2 and 220-3 constituting the second pin assembly group may be simultaneously adjusted by a lift driver 235b.

The substrate height controller 250 may control the first pin lifting means 230a to lift the first pin assembly 220-1 constituting the first pin assembly group to a relatively higher height, and control the second pin lifting means 230b to lift the second and third pin assemblies 220-2 and 220-3 constituting the second pin assembly group to a relatively lower height.

Of course, the first pin assembly group may be lifted to a lower height and the second pin assembly group may be lifted to a higher height.

As described above, in the present disclosure, a plurality of pin assemblies may be selected to form a plurality of pin assembly groups, and the height of each pin assembly group may be adjusted to adjust the lifting height of the substrate, thereby adjusting inclination of the substrate.

The substrate support unit 200 according to the present disclosure has been described as being disposed in the heat treatment device 150. However, when necessary, the substrate support unit 200 according to the present disclosure may be disposed in the plasma process device 110 of the dual process facility 100 described above. When the substrate support unit 200 is disposed in the plasma process device 110, additional configurations may be provided accordingly.

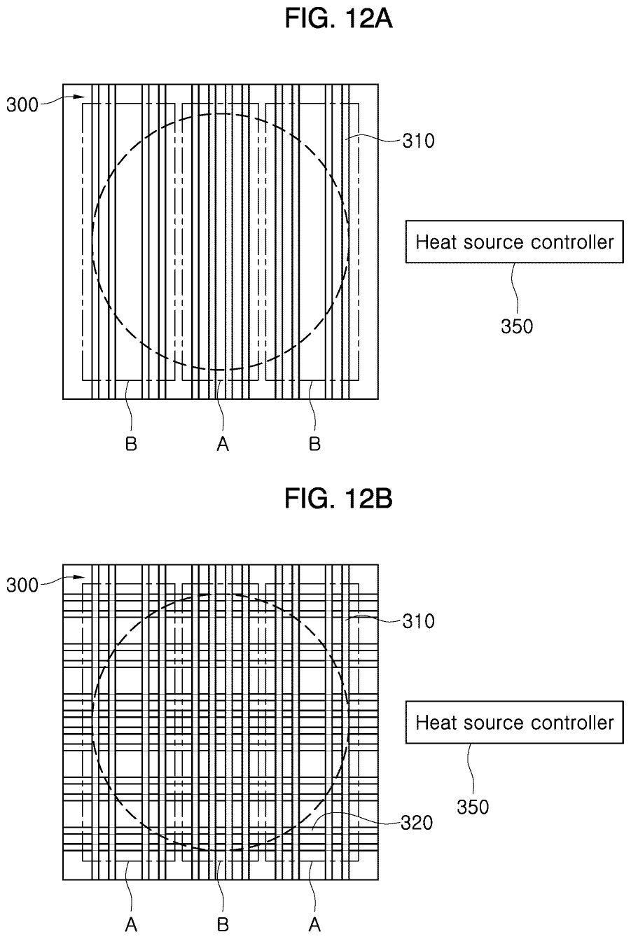

FIGS. 12A and 12B are views illustrating an embodiment of a heat source unit provided in the heat treatment device according to the present disclosure.

The embodiment illustrated in FIGS. 12A and 12B is a case where the heat source unit 300 provided in the heat treatment device 150 includes a lamp.

The heat source unit 300 may include a plurality of lamps 310.

A heat source controller 350 may control operation of the plurality of lamps 310. As an example, the lamps 310 may be divided into a plurality of heat source regions A and B corresponding to the substrate, and operation of the lamps 310 may be controlled differently for each of the heat source regions A and B. For example, the output of the lamps 310 may be adjusted for each of the heat source regions A and B to differently adjust heat emitted from the lamps 310.

As an example, as illustrated in FIG. 12A, the plurality of lamps 310 may be arranged in different numbers for each of the heat source regions A and B. For example, in the central heat source region A, the lamps 310 may be arranged relatively densely so that a larger number of lamps 310 are arranged, and in the outer heat source region B, the lamps 310 may be arranged relatively less densely so that a smaller number of lamps 310 are arranged.

In FIG. 12A, it is illustrated and described that the lamps 310 are arranged more densely in the central heat source region A than in the outer heat source region B. However, on the contrary, the lamps 310 may be arranged more densely in the outer heat source region B than in the central heat source region A.

Furthermore, the lamps 310 may be arranged in a multi-layer structure. As illustrated in FIG. 12B, the lamps 310 located at an upper position and the lamps 320 located at a lower position may be stacked perpendicular to each other to form a multi-layer lamp arrangement structure.

Through this arrangement structure, the lamp arrangement density may be adjusted differently for each of the heat source regions A and B, and the lamp output may also be adjusted differently for each of the heat source regions A and B.

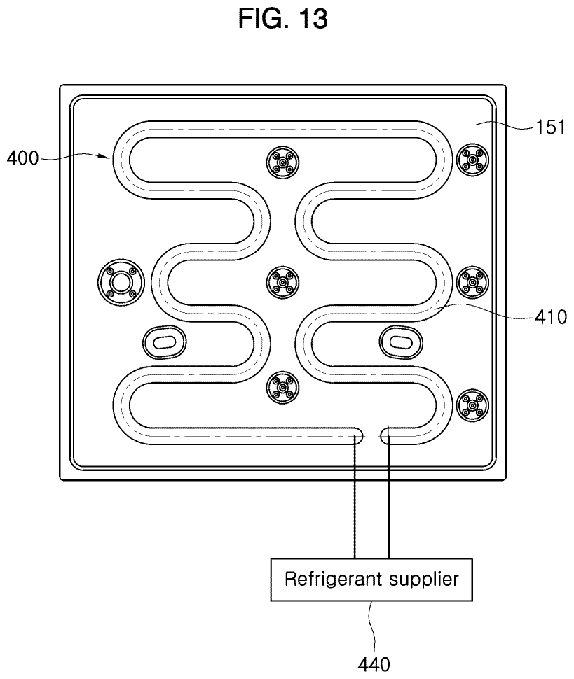

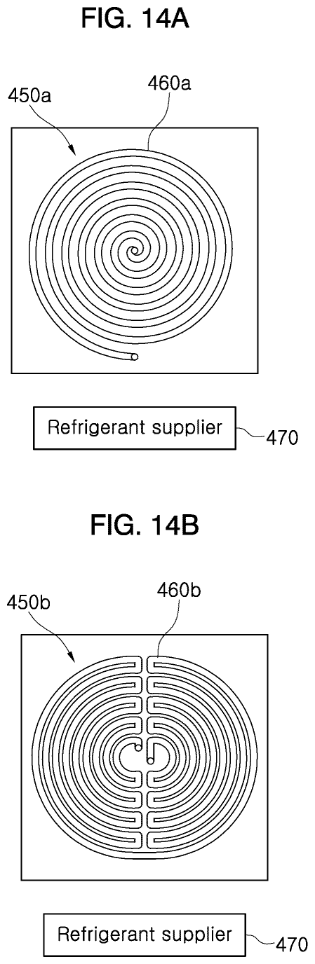

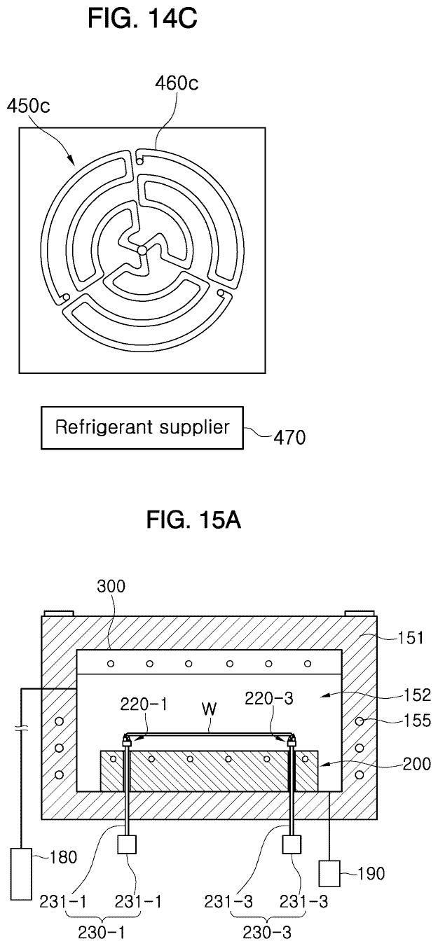

FIG. 13 and FIGS. 14A, 14B, and 14C are views illustrating an embodiment of a cooling unit provided in the heat treatment device according to the present disclosure.

FIG. 13 illustrates an embodiment of a cooling unit 400 disposed at a side wall of the heat treatment chamber 151.

The cooling unit 400 may include a side wall refrigerant flow path 410, a refrigerant supplier 440, and the like.

The side wall refrigerant flow path 410 may be provided as a flow path inside the side wall of the heat treatment chamber 151 or may be provided as a conduit on an outer surface of the side wall of the heat treatment chamber 151.

The side wall refrigerant flow path 410 may be formed in a zigzag shape, and the gap between zigzag sections of the flow path and the diameter of the flow path may be adjusted as needed.

The refrigerant supplier 440 may supply a refrigerant to the side wall refrigerant flow path 410. The refrigerant supplier 440 may include a refrigerant supply pump to adjust the supply amount of the refrigerant.

FIGS. 14A, 14B, and 14C illustrate an embodiment of a cooling unit 450 disposed on the substrate support 210 of the substrate support unit 200.

A bottom refrigerant flow path 460a, 460b, 460c of a cooling unit 450a, 450b, 450c may be provided inside the substrate support 210.

As illustrated in FIGS. 14A, 14B, and 14C, the bottom refrigerant flow path 460a, 460b, 460c may be formed in various shapes.

As an example, a portion corresponding to the substrate seated on the substrate support unit 200 may be divided into a plurality of regions to form a refrigerant flow path for each region, and the diameter and arrangement density of the refrigerant flow path may be adjusted for each region.

A refrigerant supplier 470 may supply a refrigerant to the bottom refrigerant flow path 460a, 460b, 460c. The refrigerant supplier 470 may include a refrigerant supply pump to adjust the supply amount of the refrigerant.

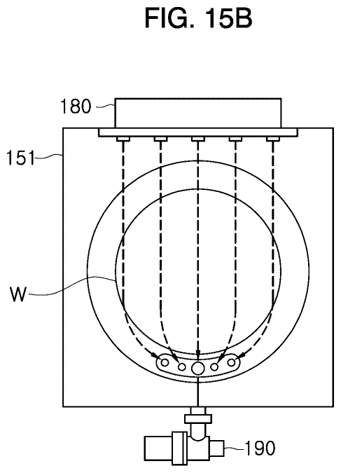

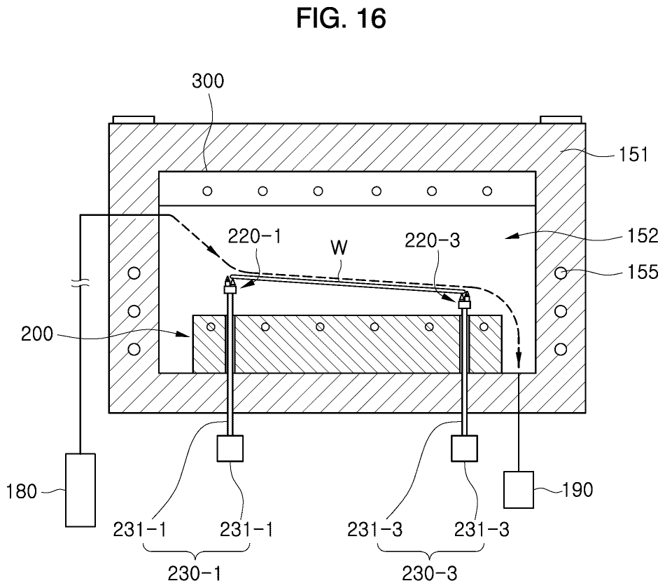

Furthermore, in the present disclosure, the flow of environment-forming gas or purge gas supplied to the heat treatment space of the heat treatment chamber and flowing along the upper surface of the substrate may be controlled. In relation to this, FIGS. 15A and 15B and FIG. 16 illustrate an embodiment of controlling a gas flow in the heat treatment device according to the present disclosure.

The heat treatment device of this embodiment is that to which the embodiment of the substrate support unit illustrated in FIGS. 4 to 9 is applied, and the embodiment of the substrate support unit illustrated in FIGS. 10 and 11 may also be applied.

While performing heat treatment on the substrate W, an environment-forming gas or purge gas may be supplied to the heat treatment space 152 of the heat treatment chamber 151 through the gas supply unit 180.

Depending on the heat treatment process performed while supplying the gas to an upper portion of the heat treatment space 152 of the heat treatment chamber 151 and the supplied gas, the substrate support unit 200 may adjust inclination of the substrate W.

As an example, the first pin assembly 220-1 may be lifted to a relatively higher height by the first pin lifting means 230-1, and the second pin assembly (not illustrated) and the third pin assembly 220-3 may be positioned relatively lower than the height of the first pin assembly 220-1 by the second lifting means (not illustrated) and the third lifting means 230-3.

Through adjustment of the height of the pin assembly, inclination of the substrate W may be adjusted. The flow of the gas may be controlled from a relatively high portion to a relatively low portion of the substrate W.

The gas flowing through the substrate W may be discharged to the outside of the heat treatment chamber 151 through a gas discharge means 190.

Through adjustment of inclination of the substrate W, the flow of the gas making contact with the substrate W may be controlled, thereby increasing the efficiency of the heat treatment process.

Although exemplary embodiments of the present disclosure have been described for illustrative purposes, those skilled in the art will appreciate that various modifications, additions, and substitutions are possible, without departing from the scope and spirit of the present disclosure. Therefore, exemplary embodiments of the present disclosure have not been described for limiting purposes, and the scope of the disclosure is not to be limited by the above embodiments. The scope of the present disclosure should be determined on the basis of the descriptions in the appended claims, and all equivalents thereof belong to the scope of the present disclosure.

What is claimed is:

1. A substrate support unit, comprising:
a substrate support configured to support a substrate;
a plurality of pin assemblies spaced apart from each other at an outer portion of the substrate support and each of which comprises a lift pin configured to lift and lower the substrate, a guide tip located outside the lift pin and configured to guide the substrate to be prevented from deviating from its position, and a body on which the lift pin and the guide tip are arranged to correspond to each other; and
a pin lifting means configured to lift and lower the bodies of the plurality of pin assemblies to adjust a height of the substrate.

2. The substrate support unit of claim 1, wherein each of the plurality of pin assemblies is configured such that the lift pin, the guide tip and the body are formed integrally.

3. The substrate support unit of claim 1, wherein each of the plurality of pin assemblies is configured such that a lift pin mounting hole and a guide tip mounting hole are provided in the body and the lift pin and the guide tip are insertedly coupled to the body.

4. The substrate support unit of claim 1, wherein an upper end of the guide tip that guides the substrate is inclined.

5. The substrate support unit of claim 1, wherein each of the plurality of pin assemblies is made of a quartz material.

6. The substrate support unit of claim 1, further comprising:
a plurality of pin lifting means configured to lift and lower the plurality of pin assemblies, respectively; and
a substrate height controller configured to control each of the plurality of pin lifting means to adjust a lifting height of each of the plurality of pin assemblies.

7. The substrate support unit of claim 1, further comprising:
a plurality of pin lifting means configured to lift a plurality of pin assembly groups, respectively, each of the plurality of pin assembly groups being composed of at least one selected from the plurality of pin assemblies; and
a substrate height controller configured to control each of the plurality of pin lifting means to adjust a lifting height of each of the plurality of pin assembly groups.

8. The substrate support unit of claim 7, wherein the substrate height controller adjusts inclination of the substrate by individually controlling the plurality of pin lifting means so that the plurality of pin assembly groups have different lifting heights.

9. A heat treatment device, comprising:
a heat treatment chamber configured to provide a heat treatment space for a substrate, wherein the substrate support unit of claim 1 is disposed in the heat treatment space of the heat treatment chamber; and
a heat source unit configured to supply heat for heat treatment of the substrate.

10. The heat treatment device of claim 9, wherein the heat source unit comprises:
a plurality of lamps; and
a heat source controller configured to divide the plurality of lamps into a plurality of heat source regions and control operation of the plurality of lamps for each of the plurality of heat source regions.

11. The heat treatment device of claim 10, wherein the heat source unit is configured such that the plurality of lamps are arranged in different numbers for each of the plurality of heat source regions.

12. The heat treatment device of claim 10, wherein the heat source unit is configured such that the plurality of heat source regions are divided into a central heat source region and an outer heat source region and the plurality of lamps are arranged in a plurality of layers in each of the plurality of heat source regions by adjusting arrangement density of the plurality of lamps.

13. The heat treatment device of claim 10, wherein the heat source controller controls output of the plurality of lamps differently for each of the plurality of heat source regions.

14. The heat treatment device of claim 9, further comprising:
a side wall refrigerant flow path formed at a wall of the heat treatment chamber; and
a refrigerant supplier configured to supply a refrigerant to the side wall refrigerant flow path.

15. The heat treatment device of claim 14, wherein the side wall refrigerant flow path is provided in a zigzag shape on the wall of the heat treatment chamber.

16. The heat treatment device of claim 9, further comprising:
a bottom refrigerant flow path formed in the substrate support unit; and
a refrigerant supplier configured to supply a refrigerant to the bottom refrigerant flow path.

17. The heat treatment device of claim 16, wherein the bottom refrigerant flow path is configured such that a portion corresponding to the substrate seated on the substrate support unit is divided into a plurality of regions to form a refrigerant flow path for each of the plurality of regions.

18. The heat treatment device of claim 9, further comprising:
a gas supply unit configured to selectively supply an environment-forming gas or a purge gas to the heat treatment space of the heat treatment chamber.

19. The heat treatment device of claim 18, wherein the substrate support unit adjusts inclination of the substrate by differently adjusting lifting heights of the plurality of pin assemblies, and
the substrate support unit adjusts a flow of the environment-forming gas or the purge gas from a first side of the substrate that is relatively high to a second side of the substrate that is relatively low through adjustment of inclination of the substrate.

20. A heat treatment device, comprising:
a heat treatment chamber configured to provide a heat treatment space for a substrate;
a substrate support unit disposed in the heat treatment space of the heat treatment chamber, and comprising a substrate support configured to support a substrate, a plurality of pin assemblies spaced apart from each other at an outer portion of the substrate support and each of which comprises a lift pin configured to lift and lower the substrate, a guide tip located outside the lift pin and configured to guide the substrate to be prevented from deviating from its position, and a body on which the lift pin and the guide tip are arranged to correspond to each other, and a pin lifting means configured to lift and lower the bodies of the plurality of pin assemblies to adjust a height of the substrate;
a plurality of pin lifting means configured to lift a plurality of pin assembly groups, respectively, each of the plurality of pin assembly groups being composed of at least one selected from the plurality of pin assemblies;
a substrate height controller configured to control each of the plurality of pin lifting means to adjust a lifting height of each of the plurality of pin assembly groups and configured to adjust inclination of the substrate by individually controlling the plurality of pin lifting means so that the plurality of pin assembly groups have different lifting heights;
a heat source unit configured to divide a portion corresponding to the substrate into a plurality of heat source regions, and comprising a plurality of lamps arranged in each of the plurality of heat source regions by adjusting arrangement density of the plurality of lamps according to the number of the plurality of lamps, and a heat source controller configured to control operation of the plurality of lamps for each of the plurality of heat source regions;
a side wall refrigerant flow path formed at a wall of the heat treatment chamber;
a bottom refrigerant flow path formed in the substrate support of the substrate support unit;
a refrigerant supplier configured to supply a refrigerant to the side wall refrigerant flow path and the bottom refrigerant flow path; and
a gas supply unit configured to supply an environment-forming gas or a purge gas to the heat treatment space of the heat treatment chamber,
wherein the substrate support unit adjusts a flow of the environment-forming gas or the purge gas from a first side of the substrate that is relatively high to a second side of the substrate that is relatively low through adjustment of inclination of the substrate.
